(19) United States
(12) Patent Application Publication
(10) Pub. No.: US 2025/0040225 A1
(43) Pub. Date: Jan. 30, 2025

(54) SEMICONDUCTOR DEVICE INCLUDING BURIED GATE STRUCTURE

(71) Applicant: SK hynix Inc., Gyeonggi-do (KR)

(72) Inventor: Yoon Jae NAM, Gyeonggi-do (KR)

(21) Appl. No.: 18/661,216

(22) Filed: May 10, 2024

(30) Foreign Application Priority Data
Jul. 24, 2023 (KR) 10-2023-0096398

(51) Int. Cl. H01L 29/423; H01L 29/66; H10B 12/00

(52) U.S. Cl. CPC H01L 29/42356; H01L 29/6656; H10B 12/482; H10B 12/485

(57) ABSTRACT

A semiconductor device includes a first buried gate configured to extend in a first direction, a bit-line contact disposed on one side of the first buried gate while being located outside the first buried gate, a storage node contact disposed on the other side of the first buried gate in a diagonal direction of the bit-line contact while being located outside the first buried gate, and active regions arranged spaced apart from each other in the first direction while overlapping with the first buried gate. Each active region includes a first extension region configured to extend in a second direction perpendicular to the first direction while overlapping with the bit-line contact, a second extension region configured to extend in the second direction while overlapping with the storage node contact, and a third extension region configured to extend in a diagonal direction while overlapping with the first buried gate.

### CROSS-REFERENCE TO RELATED APPLICATION

This patent document claims the priority and benefits of Korean patent application No. 10-2023-0096398, filed on Jul. 24, 2023, the disclosure of which is incorporated herein by reference in its entirety.

### TECHNICAL FIELD

The technology and implementations disclosed in the present disclosure generally relate to a semiconductor device, and more particularly to a semiconductor device including a plurality of active regions.

### BACKGROUND

A semiconductor device having a memory from among various semiconductor devices may include, as a device that can be used to store information, an array including individual memory cells including transistors. The semiconductor device having a memory may include, for example, a dynamic random access memory (DRAM). DRAM may include bit lines and word lines that may cross each other in a vertical direction. The bit lines and word lines may extend across an array including the memory cells. The bit lines and word lines can be used to access individual memory cells.

Memory performance, cell stability and reliability, power efficiency, ease of processing, cost, etc. can vary depending on how individual memory cells are designed and placed, and thus research on a cell array design of a memory device and a fabrication process of the cell array is being actively conducted.

### SUMMARY

Various embodiments of the disclosed technology relate to a structure in which the shape and arrangement of memory cells are efficiently designed to improve performance of a semiconductor device.

In accordance with an embodiment of the disclosed technology, a semiconductor device may include: a first buried gate configured to extend in a first direction; a bit-line contact disposed on one side of the first buried gate while being located outside the first buried gate; a storage node contact disposed on the other side of the first buried gate in a diagonal direction of the bit-line contact while being located outside the first buried gate; and a plurality of active regions repeatedly arranged spaced apart from each other by a predetermined distance in the first direction while overlapping with the first buried gate. Each of the plurality of active regions may include: a first extension region configured to extend in a second direction perpendicular to the first direction while overlapping with the bit-line contact; a second extension region configured to extend in the second direction while overlapping with the storage node contact; and a third extension region configured to extend in a diagonal direction while overlapping with the first buried gate.

In some implementations, the semiconductor device may further include: a second buried gate configured to extend in the first direction while being spaced apart from the first extension region in the second direction.

In some implementations, the first buried gate may overlap with a portion of the first extension region and a portion of the third extension region.

In some implementations, a width of the first extension region in the first direction may be greater than a width of the second extension region in the first direction.

In some implementations, the third extension regions included in active regions adjacent to each other in the diagonal direction from among the plurality of active regions may be repeatedly arranged spaced apart from each other by a predetermined distance.

In some implementations, the semiconductor device may further include: a bit line configured to extend in the second direction while overlapping with the bit-line contact; and first and second bit-line spacers, each of which contacts the bit line at both sides of the bit line, disposed not to overlap with the second extension region, and formed to extend in the second direction.

In some implementations, the first bit-line spacer and the second extension region may contact each other.

In some implementations, the first bit-line spacer and the second extension region may be spaced apart from each other.

In some implementations, the bit line may be disposed on a substrate including a semiconductor layer in which the first buried gate is disposed.

In some implementations, the bit line may be disposed to be buried in a substrate including a semiconductor layer in which the first buried gate is disposed.

In accordance with another embodiment of the disclosed technology, a semiconductor device may include: a bit line configured to extend in a first direction; a first extension region configured to extend in the first direction while overlapping with the bit line; a second extension region spaced apart from the bit line and formed to extend in the first direction; a third extension region, one end of which contacts one side of the first extension region arranged in the first direction and extends in a second direction that forms an obtuse angle with respect to the first direction, and the other end of which contacts one side of the second extension region arranged in the first direction; a first buried gate configured to overlap at least a portion of the third extension region and to extend in a third direction perpendicular to the first direction within a semiconductor layer; a bit-line contact disposed in the first extension region; and a storage node contact disposed in the third extension region.

In some implementations, the semiconductor device may further include a second buried gate spaced apart from the first extension region in the first direction, and formed to extend in a third direction.

In some implementations, the first buried gate may overlap with a portion of the second extension region, and the second buried gate may overlap with a portion of the first extension region.

In some implementations, a width of the first extension region in the third direction may be identical to a width of the third extension region in the third direction.

In some implementations, a width of the third extension region in the second direction may be greater than a width of the first extension region in the second direction.

In some implementations, the semiconductor device may further include: first and second bit-line spacers, each of which contacts the bit line at both sides of the bit line, disposed not to overlap with the first extension region, and formed to extend in the first direction.

In some implementations, the first bit-line spacer and the second extension region may be spaced apart from each other.

In some implementations, the first bit-line spacer and the second extension region may contact each other.

In some implementations, the bit line may be disposed outside the semiconductor layer.

In some implementations, the bit line may be disposed to be buried in the semiconductor layer.

It is to be understood that both the foregoing general description and the following detailed description of the disclosed technology are illustrative and descriptive and are intended to provide further description of embodiments of the present disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a plan view illustrating a cell array of a memory device that may be included in a semiconductor device based on some implementations of the disclosed technology.

FIG. 2 is a plan view illustrating a cell array of a memory device based on some other implementations of the disclosed technology.

FIG. 3 is a plan view illustrating a cell array of a memory device based on some other implementations of the disclosed technology.

FIG. 4 is a plan view illustrating a cell array of a memory device based on some other implementations of the disclosed technology.

FIG. 5 is a plan view illustrating a cell array of a memory device based on some other implementations of the disclosed technology.

FIG. 6 is a cross-sectional view illustrating the memory device taken along the line I-I′ of FIG. 1 based on some implementations of the disclosed technology.

FIG. 7 is a cross-sectional view illustrating the memory device taken along the line II-II′ of FIG. 1 based on some implementations of the disclosed technology.

FIG. 8 is a cross-sectional view illustrating the memory device taken along the line III-III′ of FIG. 1 based on some implementations of the disclosed technology.

FIG. 9 is a cross-sectional view illustrating the memory device taken along the line IV-IV′ of FIG. 1 based on some implementations of the disclosed technology.

FIG. 10 is a cross-sectional view illustrating the memory device taken along the line V-V′ of FIG. 1 based on some implementations of the disclosed technology.

### DETAILED DESCRIPTION

The present disclosure provides implementations and examples of a semiconductor device including a plurality of active regions that may be used in configurations to substantially address one or more technical or engineering issues and to mitigate limitations or disadvantages encountered in some other semiconductor device designs. Some implementations of the disclosed technology relate to a structure in which the shape and arrangement of memory cells are efficiently designed to improve performance of a semiconductor device. In recognition of the issues above, the disclosed technology provides a semiconductor device which can facilitate a fabrication process of bit-line contacts and storage node contacts, and can secure contact regions, thereby securing necessary resistance. In addition, the disclosed technology can provide a memory semiconductor device in which a large fin region is secured by the shape of the active regions and capacitance is secured through arrangement in which the active regions are regularly spaced apart from each other.

Reference will now be made in detail to the embodiments of the disclosed technology, which are illustrated in the accompanying drawings. Wherever possible, the same reference numbers will be used throughout the drawings to refer to the same or like parts. While this disclosure is susceptible to various modifications and alternative forms, specific embodiments thereof are shown by way of the drawings. However, this disclosure should not be construed as being limited to the embodiments set forth herein. Further, in the following description of embodiments of the disclosed technology, a detailed description of known functions and configurations incorporated herein will be omitted to avoid obscuring the subject matter of the embodiments.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

In describing the components of the embodiments of the disclosed technology, various terms such as first, second, etc., may be used solely for the purpose of differentiating one component from another, but the essence, order and sequence of the components are not limited to these terms. Unless defined otherwise, all terms, including technical and scientific terms, used in the disclosed technology may have the same meaning as commonly understood by a person having ordinary skill in the art to which the disclosed technology pertains. It will be further understood that terms, such as those defined in commonly used dictionaries, may be interpreted as having a meaning that is consistent with their meaning in the context of the related art and the disclosed technology, and should not be interpreted in an idealized or overly formal sense unless expressly so defined herein.

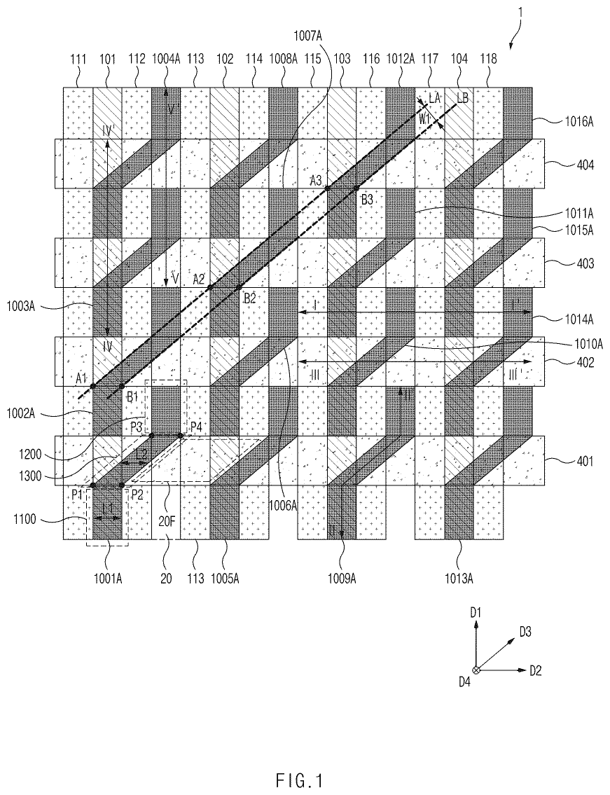

FIG. 1 is a plan view illustrating a cell array of a memory device 1 that may be included in a semiconductor device based on some implementations of the disclosed technology.

Referring to FIG. 1, the memory device 1 based on some implementations of the disclosed technology may be a portion of a semiconductor device that can function as a data storage device that can be included in various electronic devices such as computers or the like. A semiconductor device including the memory device 1 can store data or provide stored data using a central processing unit (CPU) and a memory device 1 of the electronic device. In some implementations, the semiconductor device may be a volatile memory device (e.g., a dynamic random access memory (DRAM)). In some other implementations, the semiconductor device may be a non-volatile memory device (e.g., a NAND memory).

For example, the memory device 1 may include first to fourth bit lines (101˜104), first to eighth bit-line spacers (111˜118), first to fourth buried gates (401˜404), first to sixteenth active regions (1001A˜1016A), and a deactivation region 20. The numbers of bit lines, bit-line spacers, buried gates, and active regions included in the memory device 1 are disclosed only for illustrative purposes, and the scope of the disclosed technology is not limited thereto. FIG. 1 is a plan view illustrating an example of 16 active regions arranged in a (4×4) matrix, but the scope of the disclosed technology is not limited thereto. That is, the memory element 1 may include at least one active region arranged in an (M×N) matrix, where each of M and N is an integer of 1 or more, and may include bit lines, bit-line spacers, buried gates, and deactivation regions corresponding to at least one active region. Each unit cell in a cell array of the memory device 1 may include one active region.

The first to fourth bit lines (101˜104) may be arranged parallel to each other at predetermined intervals (i.e., at intervals of a predetermined distance), and may extend in a first direction D1. The predetermined intervals may be spaced apart from each other by a predetermined distance. In detail, the predetermined intervals may be arranged spaced apart from each other in a second direction D2 perpendicular to the first direction D1. Each of the first to fourth bit lines (101˜104) may be used to read data, respectively, from capacitors (i.e., from a first to a sixteenth capacitors) electrically connected to the first to sixteenth active regions (1001A˜1016A), or may be used to write data in the capacitors. The operation of writing data in the capacitors electrically connected to the first to sixteenth active regions (1001A˜1016A) may include an operation of applying a voltage signal to the active regions (1001A˜1016A) connected to the capacitors scheduled to store desired data. Here, the operation of applying the voltage signal to the active regions (1001A˜1016A) may be performed through the first to fourth bit lines (101˜104) electrically connected to the first to sixteenth active regions (1001A˜1016A). For example, the operation of writing data in the capacitor which is electrically connected to the first active region 1001A may be performed by applying a voltage signal to the first bit line 101.

The first to eighth bit-line spacers (111˜118) may be arranged to contact both sides of the first to fourth bit lines (101˜104) arranged parallel to each other at intervals of a predetermined distance. In FIG. 1, a pattern corresponding to first to eighth bit-line spacers (111˜118) is omitted from a portion in which the first to eighth bit-line spacers (111˜118) overlap with the first to fourth buried gates (401˜404) for convenience of illustration, but may have a structure consecutively extending in the first direction D1. In one example, the first bit-line spacer 111 may extend in the first direction D1 while contacting one side surface of the first bit line 101, and the second bit-line spacer 112 may extend in the first direction D1 while contacting the other side surface of the first bit line 101. The first and second bit-line spacers (111, 112) may prevent electrical interaction that may occur between the first bit line 101 and the second bit line 102 adjacent to the first bit line 101. When electrical interaction occurs between the two adjacent bit lines (101, 102), interference may occur in an operation of reading or writing data, thereby causing unexpected errors in an operation of processing such data. The first to eighth bit-line spacers (111˜118) may be disposed to contact the first to fourth bit lines (101˜104) to electrically isolate the first to fourth bit lines (101˜104) from each other. As a result, leakage current can be prevented and the interference phenomenon can also be prevented.

The first to fourth buried gates (401˜404) may be arranged parallel to each other at predetermined intervals (i.e., at intervals of a predetermined distance), and may extend in the second direction D2. The predetermined intervals may be spaced apart from each other by a predetermined distance. In detail, the predetermined intervals may be arranged spaced apart from each other in the first direction D1. The first to fourth buried gates (401˜404) may be used to read data from capacitors electrically connected to the first to fourth bit lines (101˜104) and the first to sixteenth active regions (1001A˜1016A), or may be used to write data in the capacitors. Each of the first to fourth buried gates (401˜404) may be disposed to vertically cross the first to fourth bit lines (101˜104), and may function as a word line that selects one active region among the active regions (1001A˜1016A) to read or write data. For example, when the first bit line 101 and the first buried gate 401 are selected, the first active region 1001A may be selected. More specifically, when a voltage is applied to the first bit line 101 and a voltage equal to or greater than a threshold voltage is applied to the first buried gate 401, the charges from the first bit line 101 may move to a second extension region 1200 through a third extension region 1300 disposed to overlap with the first buried gate 401 after passing through the first extension region 1100. Then, the charges moved to the second extension region 1200 may move to the capacitor electrically connected to the second extension region 1200.

A portion (e.g., a first extension region 1100) of the first to sixteenth active regions (1001A˜1016A) may overlap with the first to fourth bit lines (101˜104), and another portion (e.g., a third extension region 1300) of the first to sixteenth active regions (1001A˜1016A) may overlap with the first to fourth buried gates (401˜404). The first to sixteenth active regions (1001A˜1016A) may have the same shape. Each of the first to sixteenth active regions (1001A˜1016A) may include a first extension region 1100, a second extension region 1200, and a third extension region 1300. Although the first to third extension regions (1100, 1200, 1300) are shown only in the first memory cell 1001A in FIG. 1, the first to third extension regions (1100, 1200, 1300) can also be commonly applied to the second to sixteenth memory cells (1002A˜1016A), but are shown in the first memory cell 1001A for convenience of description. The following example in which the first to third extension regions (1100, 1200, 1300) are applied to the first active region 1001 will hereinafter be described for convenience of description.

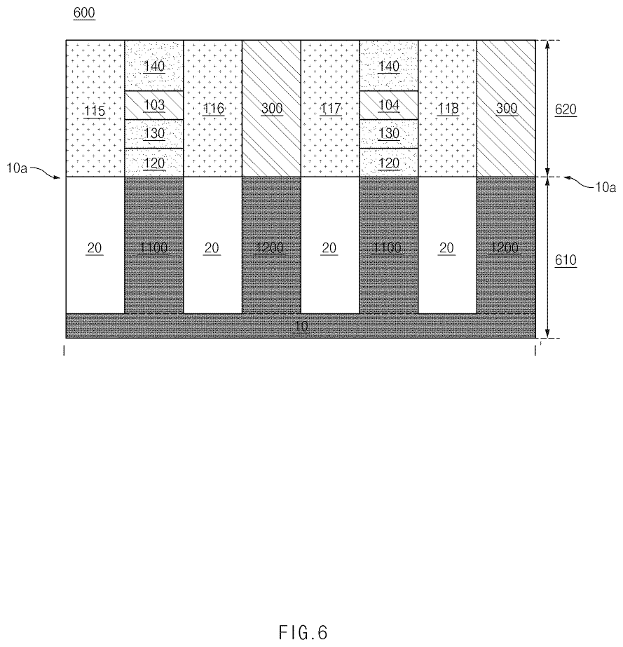

The first active region 1001A may refer to a region in which charges move from the first bit line 101 to which a voltage for reading or writing data is applied. When a voltage is applied to the first bit line 101 and the first buried gate 401 is selected, charges may be stored in a capacitor electrically connected to the first active region 1001A. The first active region 1001A may contact a bit-line contact (not shown) and a storage node contact (not shown). The bit-line contact and the storage node contact will be described later with reference to the drawings from FIG. 6.

The first extension region 1100 may refer to a region that does not overlap with the first buried gate 401 and extends in the first direction D1 from a portion formed to overlap with the first bit line 101 at one side of the first buried gate 401. The first extension region 1100 may extend until overlapping with another buried gate (not shown) that may be located below the first buried gate 401. The bit-line contact may be disposed in the first extension region 1100. When the first extension region 1100 is formed to extend to an adjacent buried gate, the bit-line contact arranged in the first extension region 1100 can be sufficiently increased in size. When the bit-line contact is enlarged, electrical resistance against the flow of current according to a voltage received from the first bit line 101 can be reduced. When the electrical resistance of the bit-line contact decreases, a difference between the voltage applied to the first bit line 101 and the voltage applied to the first extension region 1100 may decrease, thereby reducing power consumption.

The second extension region 1200 may be disposed between the second bit-line spacer 112 and the third bit-line spacer 113. Additionally, the second extension region 1200 may extend in the first direction D1 from the other side surface of the first buried gate 401 without overlapping with the first buried gate 401. The second extension region 1200 may extend until overlapping with the second buried gate 402. The storage node contact may be disposed in the second extension region 1200. When both sides of the second extension region 1200 are disposed to contact the second bit-line spacer 112 and the third bit-line spacer 113, a larger region can be secured as compared to a case in which the second extension region 1200 is spaced apart from each of the second and third bit-line spacers 112 and 113. As a result, the storage node contact that can be disposed in the second extension region 1200 can be more enlarged, and the electrical resistance against the flow of current in response to the voltage received from the first bit line 101 can be reduced. When the electrical resistance of the storage node contact decreases, the speed of accessing data in the capacitor of the first active region 1001A can increase, so that a data transfer rate can increase and the memory device 1 can improve power efficiency by reducing voltage loss.

The third extension region 1300 may contact the first extension region 1100 at a first line segment, e.g., a line segment P1-P2 where the first extension region 1100 contacts the first buried gate 401, and may also contact the second extension region 1200 at a second line segment, e.g., a line segment P3-P4 where the second extension region 1200 contacts the first buried gate 401. The third extension region 1300 may overlap with the first buried gate 401. More specifically, the third extension region 1300 may be a region that extends from a first line segment, e.g., a line segment P1-P2 in the third direction D3 and extends to a second line segment, e.g., a line segment P3-P4. The third direction D3 may form an acute angle with either the first direction D1 or the second direction D2. In some implementations, the acute angle may range from 30 degrees to 60 degrees. A width W1 of the third extension region 1300 may be constant. The width L2 of the third extension region 1300 to the second direction D2 may be equal to the width L1 of the first extension region 1100 to the second direction D2.

The first point P1 may be located at an equivalent position as the fifth to seventh points (A1, A2, A3). The first point P1 may be any one of points that contact any one of the first to fourth buried gates (401˜404), contact any one of the first to fourth bit lines (101˜104), and constitute the border of the first to sixteenth active regions (1001A˜1016A). In more detail, the first point P1 may be a point corresponding to any one of vertices having a range that has an interior angle of 180 degrees with respect to the example structure of FIG. 1. The second point P2 may be located at the equivalent position as the eighth to tenth points (B1, B2, B3). The second point P2 may be any one of points that contact any one of the first to fourth buried gates (401˜404), contact any one of the first to fourth bit lines (101˜104), and constitute the border of the first to sixteenth active regions (1001A˜1016A). In more detail, the second point P2 may be a point corresponding to any one of vertices having a range that has an interior angle of 180 degrees with respect to the example structure of FIG. 1.

Active regions belonging to the same column as the first active region 1001A may be arranged spaced apart from each other by a first distance (i.e., a first interval) in the first direction D1. For example, the second active region 1002A may be arranged spaced apart from the first active region 1001A by the first distance in the first direction D1, and the third active region 1003A may be arranged spaced apart from the second active region 1002A by the first distance in the first direction D1. The first distance may be equal to the sum of a width (to the first direction D1) of the buried gates (401˜404) and a distance between the first buried gate 401 and the second buried gate 402.

Active regions belonging to the same row as the first active region 1001A may be arranged spaced apart from each other by a second distance (i.e., a first interval) in the second direction D2. The second distance may be equal to the sum of a width of the first bit line 101 extending in the second direction D2 and a distance between the first bit line 101 and the second bit line 102. For example, the fifth active region 1005A may be spaced apart from the first active region 1001A by the second distance, and the ninth active region 1009A may be spaced apart from the fifth active region 1005A by the second distance.

According to the arrangement structure in which a plurality of active regions are spaced apart from each other in the column and row directions, the sixth, eleventh, and sixteenth active regions (1006A, 1011A, 1016A) may be sequentially spaced from each other by a predetermined distance in the third direction D3.

The fifth to seventh points (A1, A2, A3) may be points located on one virtual straight line called a straight line A (i.e., LA). The eighth to tenth points (B1, B2, B3) may also be points located on one virtual straight line called a straight line B (i.e., LB). A distance between the straight line A and the straight line B may be equal to a distance W1 between the third line segment, e.g., line segment P1-P3 and the fourth line segment, e.g., line segment P2-P4 of the third extension region 1300. The third extension region 1300 may be disposed in a region where the first to fourth buried gates (401˜404) and a region between the straight lines A and B overlap each other. The straight line A and the straight line B are virtual straight lines, FIG. 1 illustrates only a case in which the straight lines A and B pass through the second active region 1002A, the seventh active region 1007A, and the twelfth active region 1012A, other implementations are also possible, and it should be noted that the straight lines A and B can also be equally applied to the plurality of active regions arranged in the third direction D3. The positional relationship between the A straight line (LA) and the A straight line (LB) of the fifth to tenth points (A1˜A3 and B1˜B3) may correspond to one embodiment of the disclosed technology, but the scope of the disclosed technology is not limited thereto.

A deactivation region 20 may refer to the remaining region obtained when the first to sixteenth active regions (1001A˜1016A) are subtracted from the cell array of the memory device 1. Because it is difficult to show the remaining regions other than the first to sixteenth active regions (1001A˜1016A) in the drawing, the deactivation region 20 is illustrated as a portion of a space between the second bit-line spacer 112 and the third bit-line spacer 113 in the drawing, other implementations are also possible, and it should be noted that the remaining regions may be a region corresponding to the remaining region other than the first to sixteenth active regions (1001A˜1016A) in the cell array of the memory device 1. In one embodiment, the first to fourth buried gates (401˜404) may be disposed in a substrate region (see 610 in FIG. 6) including a semiconductor layer, and the first to sixteenth active regions (1001A˜1016A) may be regions included in the substrate region. The first to fourth bit lines (101˜104) and the first to eighth bit-line spacers (111˜118) may be disposed in an interconnect region (see 620 in FIG. 6) disposed on the substrate region. The deactivation region 20 may be disposed in the remaining substrate region where the first to sixteenth active regions (1001A˜1016A) are not disposed in the substrate region. The deactivation region 20 may be recessed from a top surface (see 10a in FIG. 6) of the substrate region in a fourth direction D4 perpendicular to all of the first to third directions D1 to D3, and may be disposed to a predetermined depth. The deactivation region 20 may prevent electrical interaction between adjacent active regions 1001A˜1016A from among the active regions through a structure in which the insulation material is arranged at a deep depth in the fourth direction D4, and may also prevent damage to data stored in the capacitor of the active region of the memory device 1. For example, a fin space 20F disposed between the first active region 1001A and the fifth active region 1005A may correspond to a portion of the deactivation region 20. When a voltage is applied from the first bit line 101 to the first active region 1001A, the charges may move to the second extension region 1200 along a charge transfer path that may be formed at a lower portion of the first buried gate 401 that overlaps the third extension region 1300 through the first extension region 1100 formed to overlap with the first bit line 101. The charges moved to the second extension region 1200 through the charge transfer path may move to the capacitor of the first active region 1001A through a storage node contact that can be disposed in the second extension region 1200, and may be stored in the capacitor. The deactivation region 20 including the fin region 20F may have a structure disposed deeper than the first buried gate 401. Due to the depth difference, the deactivation region 20 including the fin region 20F may prevent charges from leaking into the fifth active region 1005A, which is one of the active regions adjacent to the first active region 1001A, in the series of charge transfer processes. The fin region 20F is shown for convenience only between the first active region 1001A and the fifth active region 1005A. The deactivation region 20 disposed between the active regions spaced apart from each other in the second direction D2 may be referred to as a fin region 20F. For the plurality of active regions spaced apart from each other in the first direction D1 or the third direction D3, an insulation structure in which portions of the deactivation region 20 disposed between the active regions (1001A˜1016A) are formed to be deeper than each of the buried gates (401˜404) is used, thereby preventing charge movement between the active regions (1001A˜1016A). As the deactivation region 20 blocks charge movement between the active regions (1001A˜1016A), the number of errors in the operation of reading, writing or storing data in the capacitor of each of the active regions (1001A˜1016A) can be reduced, and the reliability of the memory device 1 can be improved.

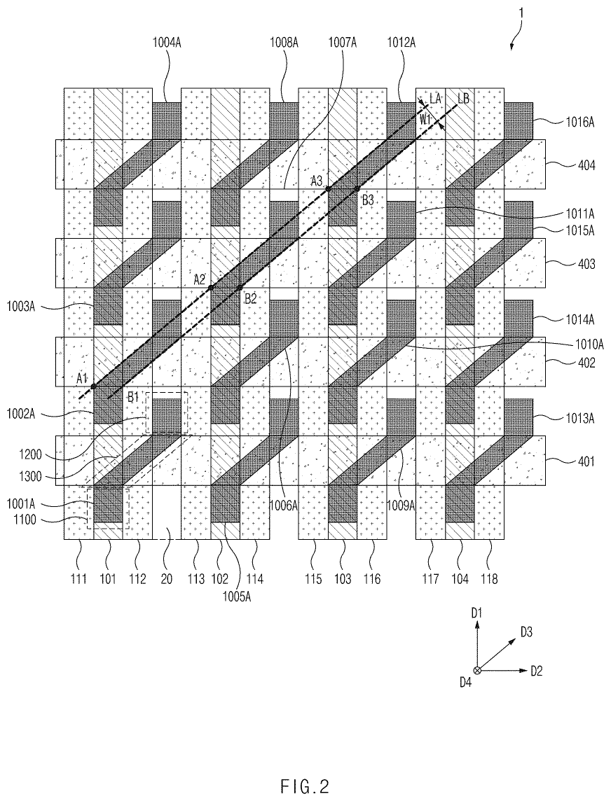

FIG. 2 is a plan view illustrating a cell array of a memory device based on some other implementations of the disclosed technology.

The structure of FIG. 2 will be described centering upon differences between FIG. 2 and FIG. 1 to avoid redundant description.

Referring to FIGS. 1 and 2, each of the first to sixteenth active regions (1001A˜1016A) of FIG. 2 may include a first extension region 1100, a second extension region 1200, and a third extension region 1300. The difference between the cell array of the memory device 1 according to the embodiment of FIG. 1 and the cell array of the memory device 1 according to the embodiment of FIG. 2 may be the arrangement range of the first and second extension regions 1100 and 1200.

In the description of the first active region 1001A, the first extension region 1100 may extend to a range where the first extension region 1100 is disposed apart from an adjacent buried gate (not shown) arranged in a downward direction, and the second extension region 1200 may extend to a range where the second extension region 1200 does not contact the second buried gate 402 acting as an adjacent buried gate arranged in an upward direction. A memory device 1 having a cell array in which each of the first and second extension regions (1100, 1200) is arranged to extend only to a range where each of the first and second extension regions 1100 and 1200 is spaced apart from an adjacent gate thereof, may be designed to prevent electrical interaction between the adjacent gate and the first or second extension region 1100 or 1200, so that the reliability of data can be improved.

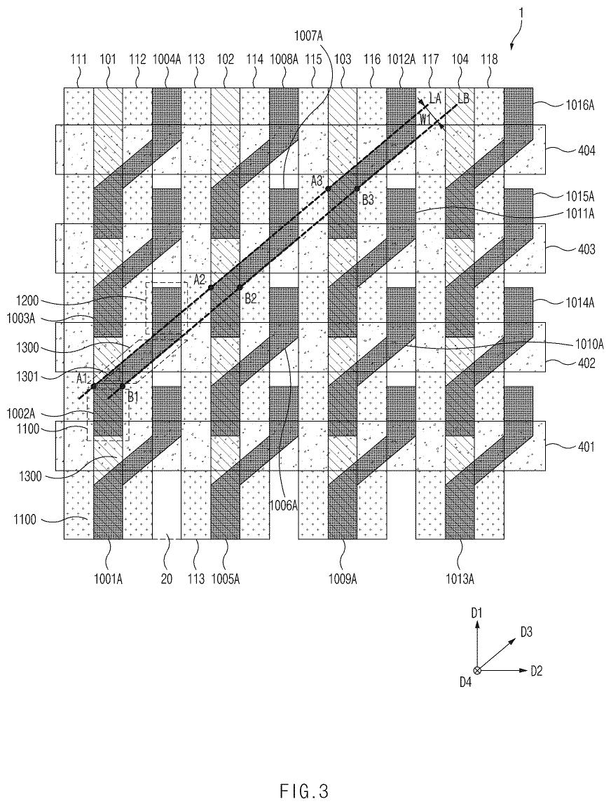

FIG. 3 is a plan view illustrating a cell array of a memory device based on some other implementations of the disclosed technology.

The structure of FIG. 3 will be described centering upon differences between FIG. 3 and FIG. 1 to avoid redundant description. Referring to FIGS. 1 and 3, the active regions (1001A˜1016A) of FIG. 3 may be substantially identical in shape and repeated arrangement structure to the active regions (1001A˜1016A) of FIG. 1. However, the arrangement positions of the buried gates (401˜404) shown in FIG. 3 may be different from those of the buried gates (401˜404) shown in FIG. 1. In addition, a bit-line contact may be disposed not only in the first extension region 1100, but also in a portion 1301 that overlaps the first bit line 101 in the third extension region 1300.

The structure of FIG. 3 will hereinafter be described based on the second active region 1002A for convenience of description. The first to third buried gates (401˜403) may be disposed in the structure of FIG. 3 in a manner that the first extension region 1100 of the second active region 1002A partially overlaps the first buried gate 401 acting as an adjacent buried gate, the second extension region 1200 partially overlaps the buried gate 402, and the second extension region 1200 is spaced apart from the third buried gate 403 acting as an adjacent buried gate. The distance between the first and second buried gates 401 and 402 may be identical to the distance between the second and third buried gates 402 and 403. According to the embodiment shown in FIG. 3, a region in which the bit-line contact can be disposed can be enlarged, so that electrical resistance to a voltage received from the first bit line 101 can be reduced. In addition, the storage node contact may cause electrical interference with the third buried gate 403 acting as an adjacent gate to which a voltage can be applied, and the structure where the second extension region 1200 in which the storage node contact can be disposed is spaced apart from the third buried gate 403 may block the electrical interference.

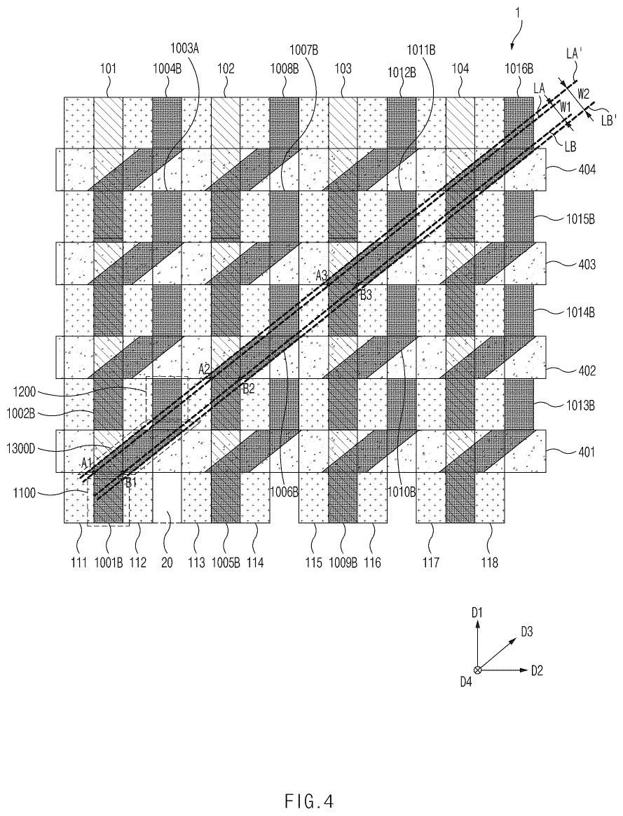

FIG. 4 is a plan view illustrating a cell array of a memory device based on some other implementations of the disclosed technology.

The structure of FIG. 4 will be described centering upon differences between FIG. 4 and FIG. 1 to avoid redundant description.

Referring to FIGS. 1 and 4, the third extension regions 1300D of the first to the sixteenth active regions (1001B˜1016B) of FIG. 4 may be different in structure from the third extension regions 1300 of the first to sixteenth active regions (1001A˜1016A) of FIG. 1.

A virtual straight line A (LA) and a virtual straight line B (LB) of FIG. 4 may be equivalent to the virtual straight line A (LA) and the virtual straight line B (LB) of FIG. 1, respectively. A virtual straight line A′ (LA′) may be a virtual straight line extending from one end of the third extension region 1300D in the third direction D3, and a virtual straight line B′ (LB′) may be a virtual straight line extending from the other end of the third extension region 1300D in the third direction D3. When the distance between the virtual straight line A (LA) and the virtual straight line B (LB) is W1 and the distance between the virtual straight line A′ (LA′) and the virtual straight line B′ (LB′) is W2, W2 may have a value greater than W1. W2 may refer to the width of the third extension region 1300D extending in the third direction D3, and the width W2 of the third extension region 1300D of FIG. 4 may be greater than the width W1 of the third extension of FIG. 1. When the width W2 of the third extension region 1300D in the third direction D3 increases and a voltage for writing data is applied to the first bit line 101 formed to overlap with the first extension region 1100, the charge transfer path that can be formed in a lower portion (arranged in the direction D4) of the first buried gate 401 in the third extension region 1300D can be elongated, thereby increasing the data transfer rate.

The width of the third extension region 1300D in the second direction D2 may be greater than the width of the first extension region 1100 in the second direction D2. The third extension region 1300D of FIG. 4, which has a width larger than the width L2 of the third extension region 1300 of FIG. 1 in the second direction D2, can also be applied to each of FIGS. 2 and 3.

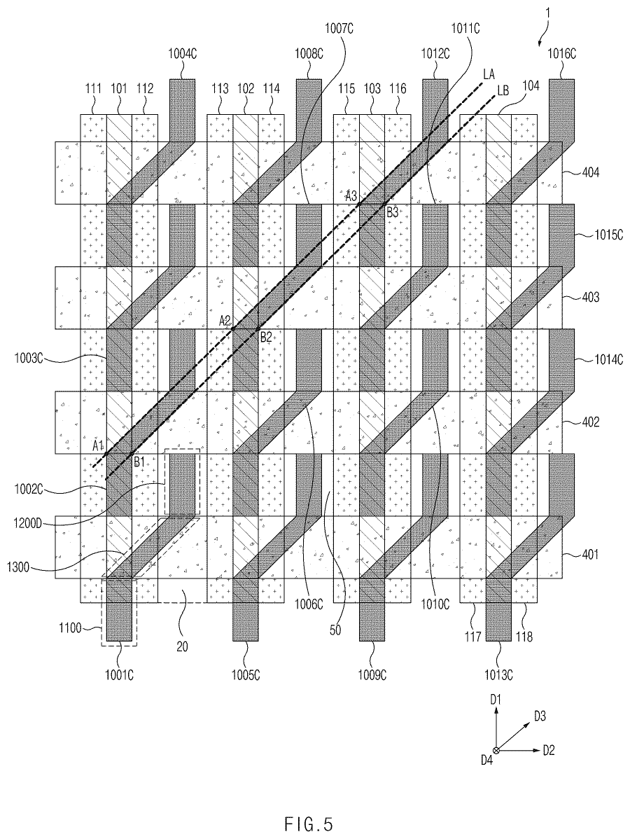

FIG. 5 is a plan view illustrating a cell array of a memory device based on some other implementations of the disclosed technology.

The structure of FIG. 5 will be described centering upon differences between FIG. 5 and FIG. 1 to avoid redundant description.

Referring to FIGS. 1 and 5, the second extension regions 1200D of the first to sixteenth active regions (1001C˜1016C) of FIG. 5 may be different in structure from the second extension regions 1200 of the first to sixteenth active regions (1001A˜1016A) of FIG. 1.

Unlike FIG. 1, referring to the first active region 1001C, the second extension region 1200D may be disposed spaced apart from each of the second and third bit-line spacers (112, 113) without contacting the second bit-line spacer 112 and the third bit-line spacers 113. A gap space 50 may be formed between the second extension region 1200D and the second bit-line spacer 112, and the gap space 50 may be formed between the second extension region 1200D and the third bit-line spacer 113. The gap space 50 may contain a material with a low dielectric constant (e.g., air).

The gap space 50 is formed between the second extension region 1200D and each of the second and third bit-line spacers 112 and 113. The gap space 50 can reduce parasitic capacitance that may occur in each of the second bit-line spacer 112 and the third bit-line spacer 113. In the arrangement of the gap space 50, the distance between the first bit line 101 and the second bit line 102 of FIG. 5 may be greater than the distance between the first bit line 101 and the second bit line 102 of FIG. 1. The gap space 50 of FIG. 5 can also be applied to each of the embodiments of FIGS. 1 to 4.

Hereinafter, an embodiment of the disclosed technology will be described with reference to the cross-sectional views of FIGS. 6 to 10 taken along the cutting lines of FIG. 1. Description of the same constituent elements of FIGS. 6 to 10 will herein be omitted for brevity to avoid redundant description thereof.

FIG. 6 is a cross-sectional view 600 illustrating an example of the memory device 1 taken along the line I-I′ of FIG. 1 based on some implementations of the disclosed technology.

Referring to FIGS. 1 and 6, the first cross-section 600 of the cell array of the memory element 1 taken along the line I-I′ shown in FIG. 1 may be an example of the cross-sectional view of the cell array taken along the line I-I′. Although the first cross-section 600 is a cross-section taken along the line I-I′ shown in FIG. 1, the scope of the disclosed technology is not limited thereto, and it should be noted that the cross-sectional view of another portion (e.g., a line alternately passing through the first and second extension regions 1100 and 1200) corresponding to the line I-I′ of the cell array of the memory device 1 may also have substantially the same structure as the first cross-section 600.

The first cross-section 600 of the cell array of the memory device 1 may include a substrate region 610, and an interconnect region 620 disposed over the substrate region 610. The substrate region 610 may include a semiconductor layer 10, at least one deactivation region 20, at least one first extension region 1100, and at least one second extension region 1200.

The semiconductor layer 10 may refer to the remaining region other than the deactivation regions 20 that are recessed from the top surface 10a of the substrate region 610 into the substrate region 610. That is, the semiconductor layer 10 may include the first extension region 1100, the second extension region 1200, the deactivation region 20, and a region disposed below a lower end of each of the first and second extension regions (1100, 1200). Although the semiconductor layer 10 is illustrated as being separated from each of the first and second extension regions 1100 and 1200 as represented by dotted lines of FIG. 6, such illustration may be used to indicate a portion corresponding to each of the first and second extension regions 1100 and 1200 of FIG. 1, and it should be noted that the first and second extension regions 1100 and 1200 may be a portion of the semiconductor layer 10. The semiconductor layer 10 may include silicon (Si).

The deactivation region 20 may be disposed to be recessed from the top surface 10a into the substrate region 610. The deactivation region 20 may comprise a plurality of deactivation regions 20 arranged spaced apart from each other by a predetermined distance along the top surface 10a. The first and second extension regions 1100 and 1200 may fill the space between adjacent deactivation regions 20 in an alternating way. The deactivation regions 20 may include an insulation material. For example, the deactivation region 20 may include at least one of silicon oxide or nitride oxide. The deactivation region 20 may prevent the movement of charges between the first and second extension regions (1100, 1200) that may be located in the space between the deactivation regions 20.

The first and second extension regions 1100 and 1200 may be alternately arranged between the deactivation regions 20 spaced apart from each other by the predetermined distance. For example, a deactivation region 20, then a first extension region 1100, then another deactivation region 20, then a second extension region 1200 may be sequentially arranged along the top surface 10a and this pattern may be repeated as many times as may be needed. Each of the first and second extension regions 1100 and 1200 may include silicon (Si). The first and second extension regions 1100 and 1200 may include the same material as the semiconductor layer 10. Each of the first and second extension regions 1100 and 1200 may include a region doped with ionic materials. For example, when the first and second extension regions 1100 and 1200 are doped with positive (+) ions (i.e., cations), the positive ions can reduce the loss of energy required for charge movement, resulting in implementation of the memory device 1 having smaller power consumption.

The interconnect region 620 may include fifth to eighth bit-line spacers (115˜118), third and fourth bit lines (103, 104), at least one bit-line contact 120, at least one barrier metal layer 130, at least one nitride pattern layer 140, and at least one storage node contact 300.

The fifth to eighth bit-line spacers (115˜118) may be disposed on the deactivation regions 20 spaced apart from each other by the predetermined distance. Each of the fifth to eighth bit-line spacers (115˜118) may completely overlap with a corresponding one of the deactivation regions 20. The width of each of the fifth to eighth bit-line spacers (115˜118) may be identical to the width of each of the deactivation regions 20.

Each of the bit-line contacts 120 may be disposed over each of the first extension regions 1100. The bit-line contact 120 may provide electrical connection between the first extension region 1100 and the third bit line 103 or electrical connection between the first extension region 1100 and the fourth bit line 104. For example, data can be read from or written in the eleventh active region 1011A. The bit-line contact 120 may include a metal material (e.g., aluminum (A1) or copper (Cu)).

A barrier metal layer 130 may be disposed between the left bit-line contact 120 and the third bit line 103 from among the two bit-line contacts 120 shown in FIG. 6, and may be disposed between the right bit-line contact 120 and the fourth bit line 104. The barrier metal layer 130 may be disposed between the bit-line contact 120 and the bit line (e.g., the third bit line 103) to reduce electrical contact resistance and serves to reduce unnecessary signal noise. The barrier metal layer 130 may include a metal material. For example, the barrier metal layer 130 may include a material containing titanium (Ti) (e.g., TiN).

A nitride pattern layer 140 may be disposed over the third bit line 103 and the fourth bit line 104. The nitride pattern layer 140 may prevent the third bit line 103 and the fourth bit line 104 from being contaminated by external substances, and may electrically insulate upper portions of the third bit line 103 and the fourth bit line 104. The nitride pattern layer 140 may include nitride (e.g., oxynitride).

The storage node contact 300 may be disposed on the second extension region 1200. The left storage node contact 300 may electrically connect the capacitor of the tenth active region 1010A (see FIG. 1) to the second extension region 1200, and the right storage node contact 300 may electrically connect the capacitor of the fourteenth active region 1014A (see FIG. 1) to the second extension region 1200. The storage node contact 300 may include a metal material. For example, the storage node contact 300 may include at least one of titanium, titanium carbide, and titanium nickel.

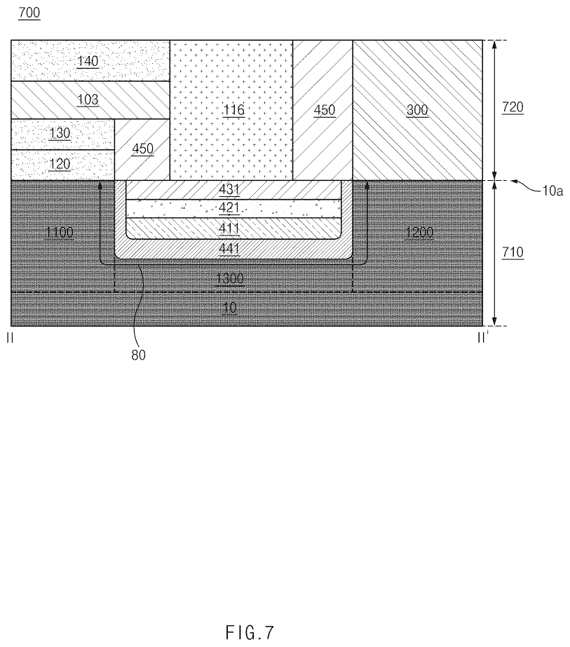

FIG. 7 is a cross-sectional view illustrating an example of the memory device 1 taken along the line II-II′ of FIG. 1 based on some implementations of the disclosed technology.

Referring to FIGS. 1 and 7, the second cross-section 700 of the cell array of the memory device 1 taken along the line II-II′ shown in FIG. 1 may be an example of the cross-sectional view of the cell array taken along the line II-II′. Although the second cross-section 700 is a cross-section taken along the line II-II′ shown in FIG. 1, the scope of the disclosed technology is not limited thereto, and it should be noted that the cross-sectional view of another portion (e.g., a line crossing one active region) corresponding to the line II-II′ of the cell array of the memory device 1 may also have substantially the same structure as the second cross-section 700.

The second cross-section 700 may include a substrate region 710 and an interconnect region 720 disposed over the substrate region 710. The substrate region 710 may include a first buried gate metal layer 411, a first buried gate insulation layer 421, a first buried gate nitride layer 431, a first buried gate oxide layer 441, a semiconductor layer 10, a first extension region 1100, a second extension region 1200, and a third extension region 1300.

The first buried gate oxide layer 441 may be disposed at the inner wall of a trench recessed from the top surface 10a. The first buried gate oxide layer 441 may prevent electrical interaction between the third extension region 1300 and the first buried gate metal layer 411. The first buried gate oxide layer 441 may include an insulation material (e.g., silicon oxide).

The first buried gate metal layer 411 may be disposed on the first buried gate oxide layer 441. The first buried gate metal layer 411 may be used to select and access the ninth active region 1009A. The first buried gate metal layer 411 may be used to apply a voltage to the ninth active region 1009A. The first buried gate metal layer 411 may include a metal material.

The first buried gate insulation layer 421 may be disposed on the first buried gate metal layer 411. The first buried gate insulation layer 421 may adjust electrical resistance of the first buried gate 401 including the first buried gate insulation layer 421 and the first buried gate metal layer 411. The first buried gate insulation layer 421 may include an insulation material (e.g., polysilicon).

The first buried gate nitride layer 431 may be disposed to extend from the first buried gate insulation layer 421 to the top surface 10a. The first buried gate nitride layer 431 can prevent a current caused by a voltage applied to the first buried gate metal layer 411 from leaking toward the top surface 10a. The first buried gate nitride layer 431 may include an insulation material (e.g., oxynitride, silicon nitride, etc.).

The third extension region 1300 may be disposed below a stack structure (hereinafter referred to as a stacked structure of the first buried gate 401) of the first buried gate oxide layer 441, the first buried gate metal layer 411, the first buried gate insulation layer 421, and the first buried gate nitride layer 431. The third extension region 1300 may be disposed between the first and second extension regions 1100 and 1200. The third extension region 1300 may be included in the semiconductor layer 10. Although the semiconductor layer 10 is illustrated as being separated from the first extension region 1100, and the second extension region 1200 as represented by dotted lines of FIG. 7, the scope of the disclosed technology is not limited thereto, such illustration may be used to indicate a portion of the second cross-section 700 corresponding to each of the extension regions (1100, 1200, 1300) of FIG. 1, and it should be noted that the third extension region 1300 may also be a region included in the semiconductor layer 10 like the first and second extension regions 1100 and 1200. The third extension region 1300 may provide a channel (or a passage) 80 (e.g., a portion of the passage 80) through which charges can move between the first and second extension regions 1100 and 1200. The third extension region 1300 may include the same material as the semiconductor layer 10. For example, the third extension region 1300 may include silicon (Si). The third extension region 1300 may include a region doped with ions. When the third extension region 1300 includes a region doped with positive (+) ions, the doped positive ions can improve carrier mobility of the channel 80 indicating a passage through which the charges move. As the carrier mobility of the channel 80 increases, the data transfer rate can also increase.

The interconnect region 720 may include a bit-line contact 120, a barrier metal layer 130, a nitride pattern layer 140, a third bit line 103, a sixth bit-line spacer 116, a contact insulation layer 450, and a storage node contact 300.

The bit-line contact 120 may be disposed on the first extension region 1100. The barrier metal layer 130 may be disposed on the bit-line contact 120. The third bit line 103 may be disposed on the barrier metal layer 130. The third bit line 103 may be disposed to be longer than the barrier metal layer 130. The nitride pattern layer 140 may be disposed on the third bit line 103. The storage node contact 300 may be disposed on the second extension region 1200. The sixth bit-line spacer 116 may be disposed on the stacked structure of the first buried gate 401, and may be disposed to have a smaller width than the stacked structure of the first buried gate 401. A portion of one side surface of the sixth bit-line spacer 116 may be in contact with the third bit line 103 and the nitride pattern layer 140. The remaining parts of one side surface of the sixth bit-line spacer 116 and the other side surface of the sixth bit-line spacer 116 may contact the contact insulation layer 450.

The contact insulation layer 450 may be disposed on the stacked structure of the first buried gate 401 in which the sixth bit-line spacer 116 is not disposed. Among the two contact insulation layers 450 shown in the second cross-section 700, the left contact insulation layer 450 may be disposed between the third bit line 103 and the top surface 10a of the substrate region 710, and the right contact insulation layer 450 may be disposed between the sixth bit-line spacer 116 and the storage node contact 300 disposed on the second extension region 1200. The contact insulation layer 450 may be in contact at its bottom surface with the top surface of the first buried gate nitride layer 431 and the top surface of the first buried gate oxide layer 441 which is at the same level as the top surface 10a of the substrate region 710. The contact insulation layer 450 may prevent electrical interaction between the third bit line 103, the bit-line contact 120, the first buried gate metal layer 411, and the storage node contact 300. The contact insulation layer 450 may include at least one of oxide or oxynitride.

When a voltage is applied to the third bit line 103 in the ninth active region 1009A, the channel 80 may be used as a charge transfer path that extends from a portion where the first extension region 1100 is in contact with the bit-line contact 120 to another portion where the second extension region 1200 is in contact with the storage node contact 300 along the third extension region 1300 disposed below the stacked structure of the first buried gate 401. When a voltage is applied to the third bit line 103, charges may move from the third bit line 103 to the first extension region 1100 through the barrier metal layer 130 and the bit-line contact 120. The charges having reached the first extension region 1100 may move to the storage node contact 300 after passing through the third extension region 1300 and the second extension region 1200 through the channel 80, so that the resultant charges can move to a capacitor electrically connected to the storage node contact 300.

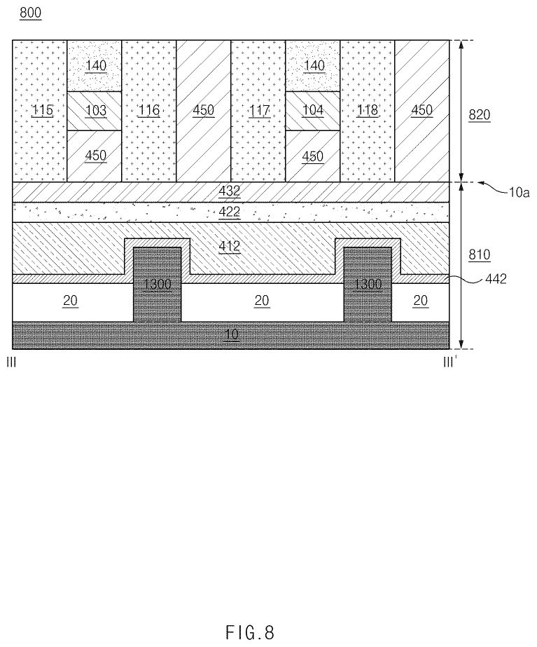

FIG. 8 is a cross-sectional view illustrating an example of the memory device taken along the line III-III′ of FIG. 1 based on some implementations of the disclosed technology.

Referring to FIGS. 1 and 8, the third cross-section 800 of the cell array of the memory device 1 taken along the line III-III′ shown in FIG. 1 may be an example of the cross-sectional view of the cell array taken along the line III-III′. Although the third cross-section 800 is a cross-section taken along the line III-III′ shown in FIG. 1, the scope of the disclosed technology is not limited thereto, and it should be noted that the cross-sectional view of another portion (e.g., a line formed to cross the buried gate in the second direction D2) corresponding to the line III-III′ of the cell array of the memory device 1 may also have substantially the same structure as the third cross-section 800.

The third cross-section 800 may include a substrate region 810 and an interconnect region 820. The substrate region 810 may include a second buried gate metal layer 412, a second buried gate insulation layer 422, a second buried gate nitride layer 432, a second buried gate oxide layer 442, a semiconductor layer 10, a third extension region 1300, and a deactivation region 20.

The second buried gate nitride layer 432 may be disposed in the substrate region 810 along the top surface 10a of the substrate region 810. The second buried gate nitride layer 432 may prevent a current caused by a voltage applied to the second buried gate metal layer 412 from leaking toward the top surface 10a. The second buried gate nitride layer 432 may include an insulation material (e.g., oxynitride, silicon nitride, etc.).

The second buried gate insulation layer 422 may be disposed below the second buried gate nitride layer 432. The second buried gate insulation layer 422 may adjust electrical resistance of the second buried gate 402 including the second buried gate insulation layer 422 and the second buried gate metal layer 412. The second buried gate insulation layer 422 may include an insulation material (e.g., polysilicon).

The second buried gate metal layer 412 may be disposed below the second buried gate insulation layer 422. The second buried gate metal layer 412 formed at a portion that is located adjacent to the deactivation region 20 in a direction perpendicular to the top surface 10a may have a larger thickness than the second buried gate metal layer 412 formed at a portion that is located adjacent to the third extension region 1300 in a direction perpendicular to the top surface 10a. The second buried gate metal layer 412 may be used to apply a voltage to the active regions (e.g., the tenth active region 1010A and the fourteenth active region 1014A of FIG. 8) connected to the second buried gate 402. The second buried gate metal layer 412 may include a metal material.

The second buried gate oxide layer 442 may be disposed below the second buried gate metal layer 412. The second buried gate oxide layer 442 may adjust electrical interaction between the second buried gate metal layer 412 and the third extension region 1300. The second buried gate oxide layer 442 may include an insulation material (e.g., silicon oxide).

Each of the deactivation regions 20 may be disposed adjacent in a direction perpendicular to the top surface 10a to regions in which the second buried gate metal layer 412 having a larger thickness is disposed, and may be in contact with the second buried gate oxide layer 442.

The third extension regions 1300 may be disposed in the spaces between the deactivation regions 20, respectively. The third extension regions 1300 may be disposed to be thicker than the deactivation regions 20 in correspondence to the structure in which the second buried gate metal layer 412 is disposed to be less thick. The semiconductor layer 10 may be disposed at a deeper depth within the substrate region 810 as compared to a region in which the deactivation regions 20 and the third extension regions 1300 are disposed in the substrate region 810.

The interconnect region 820 may include the fifth to eighth bit-line spacers (115˜118), the third and fourth bit lines (103, 104), at least one nitride pattern layer 140, and at least one contact insulation layer 450.

The fifth to eighth bit-line spacers (115˜118) may be spaced apart from each other by a predetermined distance on the top surface 10a of the substrate region 810. Each of the sixth bit-line spacer 116 and the eighth bit-line spacer 118 may be aligned and disposed on the top surface 10a of the region where the third extension region 1300 is disposed.

The third bit line 103 may be disposed between the fifth bit-line spacer 115 and the sixth bit-line spacer 116. The third bit line 103 may be disposed on the contact insulation layer 450.

The fourth bit line 104 may be disposed between the seventh bit-line spacer 117 and the eighth bit-line spacer 118. The fourth bit line 104 may be disposed on the contact insulation layer 450.

The nitride pattern layers 140 may be disposed on the third bit line 103 and the fourth bit line 104, respectively.

The contact insulation layers 450 may be disposed below the third bit line 103 and the fourth bit line 104, respectively. Each of the contact insulation layers 450 may further be disposed between the sixth bit-line spacer 116 and the seventh bit-line spacer 117. The contact insulation layer 450 may further be disposed on the right side of the eighth bit line spacer 118. The contact insulation layer 450 may be disposed in a gap space where no bit lines are disposed, from among spaces between bit-line spacers.

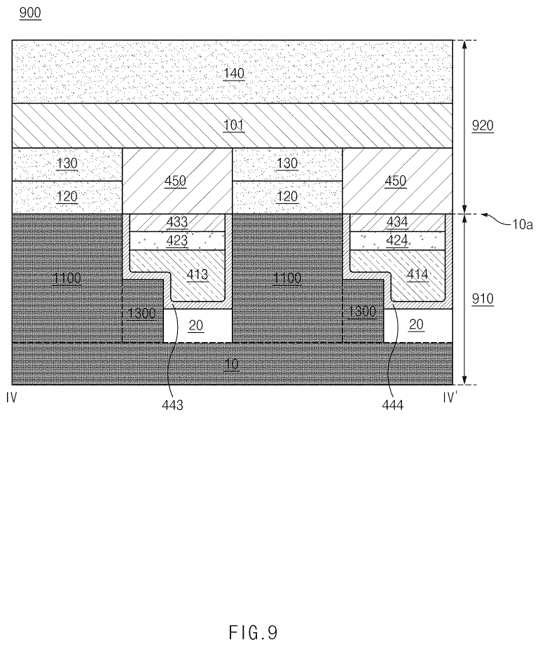

FIG. 9 is a cross-sectional view illustrating the memory device taken along the line IV-IV′ of FIG. 1 based on some implementations of the disclosed technology.

Referring to FIGS. 1 and 9, the fourth cross-section 900 of the cell array of the memory device 1 taken along the line IV-IV′ shown in FIG. 1 illustrates the cross-sectional view of the cell array taken along the line IV-IV′. Although the fourth cross-section 900 is a cross-section taken along the line IV-IV′ shown in FIG. 1, the scope of the disclosed technology is not limited thereto, and it should be noted that the cross-sectional view of another portion (e.g., a line formed to cross the bit line in the first direction D1) corresponding to the line IV-IV′ of the cell array of the memory device 1 may also have substantially the same structure as the fourth cross-section 900.

The fourth cross-section 900 may include a substrate region 910 and an interconnect region 920 disposed over the substrate region 910.

The substrate region 910 may include a third buried gate metal layer 413, a third buried gate insulation layer 423, a third buried gate nitride layer 433, a third buried gate oxide layer 443, a fourth buried gate metal layer 414, a fourth buried gate insulation layer 424, a fourth buried gate nitride layer 434, a fourth buried gate oxide layer 444, a semiconductor layer 10, at least one first extension region 1100, at least one third extension region 1300, and at least one deactivation region 20.

The third buried gate oxide layer 443 may be disposed along the inner wall of a predetermined region recessed from a portion of the top surface 10a into the substrate region 910. The first extension regions 1100 may be disposed on both sides of the third buried gate oxide layer 443, respectively. The third extension region 1300 and the deactivation region 20 may be disposed below the third buried gate oxide layer 443. The third buried gate oxide layer 443 may be disposed at a deeper depth within a region in which the third buried gate oxide layer 443 is adjacent to the deactivation region 20 as compared to another region in which the third buried gate oxide layer 443 is adjacent to the third extension region 1300. The third buried gate oxide layer 443 may prevent electrical interaction between the third buried gate metal layer 413 and the first extension region 1100, and may also prevent electrical interaction between the third buried gate metal layer 413 and the third extension region 1300. The third buried gate oxide layer 443 may include an insulation material (e.g., silicon oxide).

The third buried gate metal layer 413 may be disposed on the third buried gate oxide layer 443. The top surface of the third buried gate metal layer 413 may be formed flat. The third buried gate metal layer 413 may be used to apply a voltage to active regions connected to the third buried gate 403. The third buried gate metal layer 413 may include a metal material.

The third buried gate insulation layer 423 may be disposed on the third buried gate metal layer 413. The third buried gate insulation layer 423 may adjust electrical resistance of the third buried gate 403 including the third buried gate insulation layer 423 and the third buried gate metal layer 413. The third buried gate insulation layer 423 may include an insulation material (e.g., polysilicon).

The third buried gate nitride layer 433 may be formed to extend from the top surface of the third buried gate insulation layer 423 to the top surface 10a. The third buried gate nitride layer 433 may prevent a current caused by a voltage applied to the third buried gate metal layer 413 from leaking toward the top surface 10a. The third buried gate nitride layer 433 may include an insulation material (e.g., oxynitride, silicon nitride, etc.).

The fourth buried gate oxide layer 444 may be disposed along the inner wall of a predetermined region recessed from another portion of the top surface 10a into the substrate region 910. The first extension region 1100 may be disposed on a side surface of the fourth buried gate oxide layer 444. The third extension region 1300 and the deactivation region 20 may be disposed below the fourth buried gate oxide layer 444. The fourth buried gate oxide layer 444 may be disposed at a deeper depth in a region where the fourth buried gate oxide layer 444 is adjacent to the deactivation region 20 as compared to another region in which the fourth buried gate oxide layer 444 is adjacent to the third extension region 1300. The fourth buried gate oxide layer 444 may prevent electrical interaction between the fourth buried gate metal layer 414 and the first extension region 1100, and may also prevent electrical interaction between the fourth buried gate metal layer 414 and the third extension region 1300. The fourth buried gate oxide layer 444 may include an insulation material (e.g., silicon oxide).

The fourth buried gate metal layer 414 may be disposed on the fourth buried gate oxide layer 444 but may leave upper side portions of the fourth buried gate oxide layer 444 exposed. The fourth buried gate metal layer 414 is added up to a level that is lower than the top surface of the fourth buried gate oxide layer 444. The top surface of the fourth buried gate metal layer 414 may be formed flat and may be at a lower level than the top surface of the fourth buried gate oxide layer 444. The fourth buried gate metal layer 414 may be used to apply a voltage to active regions connected to the fourth buried gate 404. The fourth buried gate metal layer 414 may include a metal material.

The fourth buried gate insulation layer 424 may be disposed on the fourth buried gate metal layer 414. The fourth buried gate insulation layer 424 may adjust electrical resistance of the fourth buried gate 404 including the fourth buried gate insulation layer 424 and the fourth buried gate metal layer 414. The fourth buried gate insulation layer 424 may include an insulation material (e.g., polysilicon).

The fourth buried gate nitride layer 434 may be formed to extend from the top surface of the fourth buried gate insulation layer 424 to the top surface 10a. The fourth buried gate nitride layer 434 may prevent a current caused by a voltage applied to the fourth buried gate metal layer 414 from leaking toward the top surface 10a. The fourth buried gate nitride layer 434 may include an insulation material (e.g., oxynitride, silicon nitride, etc.).

Among the two first extension regions 1100, the left first extension region 1100 may contact the left side of the third buried gate oxide layer 443, and may be disposed inside the substrate region 910 from the top surface 10a. Among the two first extension regions 1100, the right first extension region 1100 may contact the right side of the third buried gate oxide layer 443, may contact the left side of the fourth buried gate oxide layer 444, and may be disposed inside the substrate region 910 from the top surface 10a.

Among the two third extension regions 1300, the left third extension region 1300 may contact a portion of the right side of the left first extension region 1100, and may be disposed below the third buried gate oxide layer 443. The left third extension region 1300 may contact the left side of the left deactivation region 20. Among the two third extension regions 1300, the right third extension region 1300 may contact a portion of the right side of the right first extension region 1100, and may be disposed below the fourth buried gate oxide layer 444. The right third extension region 1300 may contact the left side of the right deactivation region 20.

Among the two deactivation regions 20, the left deactivation region 20 may be disposed below the third buried gate oxide layer 443 that is located below a portion in which the third buried gate metal layer 413 having a larger thickness is disposed. The third extension region 1300 may be disposed on the left side of the left deactivation region 20, and the first extension region 1100 may be disposed on the right side of the left deactivation region 20. Among the two deactivation regions 20, the right deactivation region 20 may be disposed below the fourth buried gate oxide layer 444 that is located below a portion in which the fourth buried gate metal layer 414 having a larger thickness is disposed. The third extension region 1300 may be disposed on the left side of the right deactivation region 20. For example, the left deactivation region 20 can prevent electrical interaction between a predetermined channel, which can be formed in the left first extension region 1100 and the left third extension region 1300, and another predetermined channel, which can be formed in the right first extension region 1100 and the right third extension region 1300.

The semiconductor layer 10 may be disposed below the first extension regions 1100, the third extension regions 1300, and the deactivation regions 20.

The interconnect region 920 may include at least one bit-line contact 120, at least one barrier metal layer 130, at least one contact insulation layer 450, a first bit line 101, and a nitride pattern layer 140.

The bit-line contacts 120 may be disposed on the first extension regions 1100, respectively.

The barrier metal layers 130 may be disposed on the bit-line contacts 120, respectively.

Each of the contact insulation layers 450 may be disposed in a region in which the bit-line contact 120 is not disposed on the top surface 10a. The contact insulation layer 450 may be formed to extend to a lower portion of the first bit line 101.

The first bit line 101 may be disposed to be flat on the barrier metal layer 130 and the contact insulation layer 450 while having a constant thickness thereon.

The nitride pattern layer 140 may be disposed on the first bit line 101.

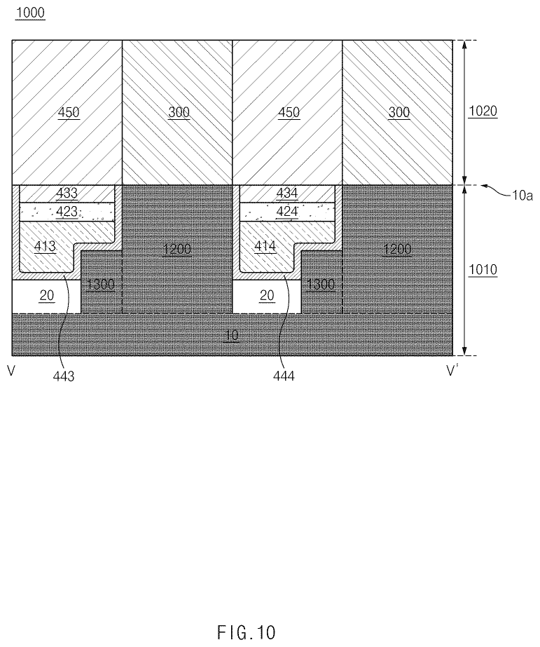

FIG. 10 is a cross-sectional view illustrating the memory device taken along the line V-V′ of FIG. 1 based on some implementations of the disclosed technology.

Referring to FIGS. 1 and 10, the fifth cross-section 1000 of the cell array of the memory device 1 taken along the line V-V′ shown in FIG. 1 illustrates the cross-sectional view of the cell array taken along the line V-V′. Although the fifth cross-section 1000 is a cross-section taken along the line V-V′ shown in FIG. 1, the scope of the disclosed technology is not limited thereto, and it should be noted that the cross-sectional view of another portion (e.g., a line formed to cross the second extension region 1200 while extending in the first direction D1) corresponding to the line V-V′ of the cell array of the memory device 1 may also have substantially the same structure as the fifth cross-section 1000.

The fifth cross-section 1000 may include a substrate region 1010 and an interconnect region 1020.

The substrate region 1010 may include a third buried gate metal layer 413, a third buried gate insulation layer 423, a third buried gate nitride layer 433, a third buried gate oxide layer 443, a fourth buried gate metal layer 414, a fourth buried gate insulation layer 424, a fourth buried gate nitride layer 434, a fourth buried gate oxide layer 444, a semiconductor layer 10, at least one second extension region 1200, at least one third extension region 1300, and at least one deactivation region 20.

The third buried gate oxide layer 443 may be disposed along the inner wall of a predetermined region recessed from a portion of the top surface 10a into the substrate region 1010. The second extension regions 1200 may be disposed on both sides of the third buried gate oxide layer 443, respectively. The third extension region 1300 and the deactivation region 20 may be disposed below the third buried gate oxide layer 443. The third buried gate oxide layer 443 may be disposed at a deeper depth within a region in which the third buried gate oxide layer 443 is adjacent to the deactivation region 20 as compared to another region in which the third buried gate oxide layer 443 is adjacent to the third extension region 1300. The third buried gate oxide layer 443 may prevent electrical interaction between the third buried gate metal layer 413 and the second extension region 1200, and may also prevent s electrical interaction between the third buried gate metal layer 413 and the third extension region 1300. The third buried gate oxide layer 443 may include an insulation material (e.g., silicon oxide).

The third buried gate metal layer 413 may be disposed on the third buried gate oxide layer 443. The top surface of the third buried gate metal layer 413 may be formed flat. The third buried gate metal layer 413 may be used to apply a voltage to active regions connected to the third buried gate 403. The third buried gate metal layer 413 may include a metal material.

The third buried gate insulation layer 423 may be disposed on the third buried gate metal layer 413. The third buried gate insulation layer 423 may adjust electrical resistance of the third buried gate 403 including the third buried gate insulation layer 423 and the third buried gate metal layer 413. The third buried gate insulation layer 423 may include an insulation material (e.g., polysilicon).

The third buried gate nitride layer 433 may be formed to extend from the top surface of the third buried gate insulation layer 423 to the top surface 10a. The third buried gate nitride layer 433 may prevent a current caused by a voltage applied to the third buried gate metal layer 413 from leaking toward the top surface 10a. The third buried gate nitride layer 433 may include an insulation material (e.g., oxynitride, silicon nitride, etc.).

The fourth buried gate oxide layer 444 may be disposed along the inner wall of a predetermined region recessed from another portion of the top surface 10a into the substrate region 1010. The second extension region 1200 may be disposed on a side surface of the fourth buried gate oxide layer 444. The third extension region 1300 and the deactivation region 20 may be disposed below the fourth buried gate oxide layer 444. The fourth buried gate oxide layer 444 may be disposed at a deeper depth in a region where the fourth buried gate oxide layer 444 is adjacent to the deactivation region 20 as compared to another region in which the fourth buried gate oxide layer 444 is adjacent to the third extension region 1300. The fourth buried gate oxide layer 444 may prevent electrical interaction between the fourth buried gate metal layer 414 and the second extension region 1200, and may also prevent electrical interaction between the fourth buried gate metal layer 414 and the third extension region 1300. The fourth buried gate oxide layer 444 may include an insulation material (e.g., silicon oxide).

The fourth buried gate metal layer 414 may be disposed on the fourth buried gate oxide layer 444. The top surface of the fourth buried gate metal layer 414 may be formed flat. The fourth buried gate metal layer 414 may be used to apply a voltage to active regions connected to the fourth buried gate 404. The fourth buried gate metal layer 414 may include a metal material.

The fourth buried gate insulation layer 424 may be disposed on the fourth buried gate metal layer 414. The fourth buried gate insulation layer 424 may adjust electrical resistance of the fourth buried gate 404 including the fourth buried gate insulation layer 424 and the fourth buried gate metal layer 414. The fourth buried gate insulation layer 424 may include an insulation material (e.g., polysilicon).

The fourth buried gate nitride layer 434 may be formed to extend from the top surface of the fourth buried gate insulation layer 424 to the top surface 10a. The fourth buried gate nitride layer 434 may prevent a current caused by a voltage applied to the fourth buried gate metal layer 414 from leaking toward the top surface 10a. The fourth buried gate nitride layer 434 may include an insulation material (e.g., oxynitride, silicon nitride, etc.).

Among the two second extension regions 1200, the left second extension region 1200 may contact the right side of the third buried gate oxide layer 443, may contact the left side of the fourth buried gate oxide layer 444, and may be disposed in the substrate region 1010 while extending from the top surface 10a. Among the two second extension regions 1200, the right second extension region 1200 may contact the right side of the fourth buried gate oxide layer 444, and may be disposed in the substrate region 1010 while extending from the top surface 10a.

Among the two third extension regions 1300, the left third extension region 1300 may contact a portion of the left side of the left second extension region 1200, and may be disposed below the third buried gate oxide layer 443. The left third extension region 1300 may contact the right side of the left deactivation region 20 from among the two deactivation region regions 20. Among the two third extension regions 1300, the right third extension region 1300 may contact the right side of the left deactivation region 20, may contact a portion of the left side of the right second extension region 1200, and may be disposed below the fourth buried gate oxide layer 444.

The left deactivation region 20 may be disposed below the third buried gate oxide layer 443 that is located below a portion in which the third buried gate metal layer 413 having a larger thickness is disposed. The third extension region 1300 may be disposed on the right side of the left deactivation region 20. Among the two deactivation regions 20, the right deactivation region 20 may be disposed below the fourth buried gate oxide layer 444 that is located below a portion in which the fourth buried gate metal layer 414 having a larger thickness is disposed. The second extension region 1200 may be disposed on the left side of the right deactivation region 20, and the third extension region 1300 may be disposed on the right side of the right deactivation region 20. For example, the right deactivation region 20 can prevent electrical interaction between a predetermined channel, which can be formed in the left second extension region 1200 and the left third extension region 1300, and another predetermined channel, which can be formed in the right second extension region 1200 and the right third extension region 1300.

The semiconductor layer 10 may be disposed below the second extension regions 1200, the third extension regions 1300, and the deactivation regions 20.

The interconnect region 1020 may include at least one storage node contact 300 and at least one contact insulation layer 450.

The storage node contacts 300 may be disposed on the second extension regions 1200, respectively.

The contact insulation layers 450 may be disposed on the top surface 10a in a region where the storage node contact 300 is not disposed. The contact insulation layer 450 may prevent electrical interaction between the storage node contacts 300, and may also prevent electrical interaction between each of the storage node contacts 300 and each of the third and fourth buried gates 403 and 404.

Referring to the above cross-sectional views of FIGS. 6 to 10 according to the embodiments of the disclosed technology, the cross-sections of FIGS. 2 to 5 can be easily modified by a person skilled in the art to which the disclosed technology pertains.

In addition, FIGS. 6 to 9 illustrate the cross-sectional views of the memory device in which the bit-line contact 120 is disposed on the top surface 10a of the substrate regions 610, 710, 810, and 910. The modified embodiment of FIG. 1 may include the bit-line contacts 120 and the first to fourth bit lines (101˜104) disposed to be buried in the substrate regions 610, 710, 810, and 910. In the modified embodiment, the first to fourth buried gates (401˜404) may be disposed at a deeper depth as compared to the embodiments of FIGS. 6 to 9. When the first to fourth bit lines (101˜104) are buried, parasitic capacitance that may be formed in the first to eighth bit-line spacers (111˜118) can be reduced.

As is apparent from the above description, the semiconductor device based on some implementations of the disclosed technology can facilitate a fabrication process of bit-line contacts and storage node contacts, and can secure contact regions, thereby securing necessary resistance. In addition, the disclosed technology can provide a memory semiconductor device in which a large fin region is secured by the shape of the active regions and capacitance is secured through arrangement in which the active regions are regularly spaced apart from each other.

The embodiments of the disclosed technology may provide a variety of effects capable of being directly or indirectly recognized through the above-mentioned embodiments of the present disclosure.

Those skilled in the art will appreciate that the disclosed technology may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and/or enhancements to the disclosed embodiments and other embodiments can be devised based on what is described and/or illustrated in the present disclosure. Furthermore, the embodiments may be combined to form additional embodiments.

What is claimed is:

1. A semiconductor device comprising:
a first buried gate configured to extend in a first direction;
a bit-line contact disposed on one side of the first buried gate while being located outside the first buried gate;
a storage node contact disposed on the other side of the first buried gate in a diagonal direction of the bit-line contact while being located outside the first buried gate; and
a plurality of active regions repeatedly arranged spaced apart from each other by a predetermined distance in the first direction while overlapping with the first buried gate,
wherein each of the plurality of active regions includes:
a first extension region configured to extend in a second direction perpendicular to the first direction while overlapping with the bit-line contact;
a second extension region configured to extend in the second direction while overlapping with the storage node contact; and
a third extension region configured to extend in a diagonal direction while overlapping with the first buried gate.

2. The semiconductor device according to claim 1, further comprising:
a second buried gate configured to extend in the first direction while being spaced apart from the first extension region in the second direction.

3. The semiconductor device according to claim 1, wherein
the first buried gate is configured to overlap with a portion of the first extension region and a portion of the third extension region.

4. The semiconductor device according to claim 1, wherein
a width of the first extension region in the first direction is greater than a width of the second extension region in the first direction.

5. The semiconductor device according to claim 1, wherein
the third extension regions included in active regions adjacent to each other in the diagonal direction from among the plurality of active regions are repeatedly arranged spaced apart from each other by a predetermined distance.

6. The semiconductor device according to claim 1, further comprising:
a bit line configured to extend in the second direction while overlapping with the bit-line contact; and
first and second bit-line spacers, each of which contacts the bit line at both sides of the bit line, disposed not to overlap with the second extension region, and formed to extend in the second direction.

7. The semiconductor device according to claim 6, wherein
the first bit-line spacer and the second extension region are configured to contact each other.

8. The semiconductor device according to claim 6, wherein
the first bit-line spacer and the second extension region are configured spaced apart from each other.

9. The semiconductor device according to claim 1, wherein
the bit line is disposed on a substrate including a semiconductor layer in which the first buried gate is disposed.

10. The semiconductor device according to claim 1, wherein
the bit line is disposed to be buried in a substrate including a semiconductor layer in which the first buried gate is disposed.

11. A semiconductor device comprising:
a bit line configured to extend in a first direction;
a first extension region configured to extend in the first direction while overlapping with the bit line;
a second extension region spaced apart from the bit line and formed to extend in the first direction;
a third extension region, one end of which contacts one side of the first extension region arranged in the first direction and extends in a second direction that forms an obtuse angle with respect to the first direction, and the other end of which contacts one side of the second extension region arranged in the first direction;
a first buried gate configured to overlap at least a portion of the third extension region and to extend in a third direction perpendicular to the first direction within a semiconductor layer;
a bit-line contact disposed in the first extension region; and
a storage node contact disposed in the third extension region.

12. The semiconductor device according to claim 11, further comprising:
a second buried gate spaced apart from the first extension region in the first direction, and formed to extend in a third direction.

13. The semiconductor device according to claim 12, wherein
the first buried gate is configured to overlap with a portion of the second extension region; and
the second buried gate is configured to overlap with a portion of the first extension region.

14. The semiconductor device according to claim 11, wherein
a width of the first extension region in the third direction is equal to a width of the third extension region in the second direction.

15. The semiconductor device according to claim 11, wherein
a width of the third extension region in the third direction is greater than a width of the first extension region in the third direction.

16. The semiconductor device according to claim 11, further comprising:
first and second bit-line spacers, each of which contacts the bit line at both sides of the bit line, disposed not to overlap with the first extension region, and formed to extend in the first direction.

17. The semiconductor device according to claim 16, wherein
the first bit-line spacer and the second extension region are configured spaced apart from each other.

18. The semiconductor device according to claim 16, wherein
the first bit-line spacer and the second extension region are configured to contact each other.

19. The semiconductor device according to claim 11, wherein
the bit line is disposed outside the semiconductor layer.

20. The semiconductor device according to claim 11, wherein
the bit line is disposed buried in the semiconductor layer.
